(19) United States
(12) Patent Application Publication
(10) Pub. No.: US 2007/0184615 A1
(43) Pub. Date: Aug. 9, 2007

(54) Process for Manufacturing a Non-Volatile Memory Electronic Device Integrated on a Semiconductor Substrate and Corresponding Device

(75) Inventors: Daniela Brazzelli, Busto Arsizio (VA) (IT); Giorgio Servalli, Ciserano (BG) (IT); Enzo Carollo, Montecchio Precalcino (VI) (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.l., Agrate Brianza (MI) (IT)

(21) Appl. No.: 11/618,370

(22) Filed: Dec. 29, 2006

(30) Foreign Application Priority Data
Dec. 30, 2005 (EP) 05425942.9

(51) Int. Cl. H01L 21/336

(52) U.S. Cl. 438/266

(57) ABSTRACT

A non-volatile memory electronic device integrated on a semiconductor substrate includes non-volatile memory cells organized in a matrix, and circuitry associated therewith. Each memory cell includes a gate electrode projecting from the semiconductor substrate. Source and drain regions are formed in the semiconductor substrate and aligned with the gate electrodes. At least one portion of the gate electrodes are insulated from each other by air-gaps which are closed on top by a third non-conforming dielectric layer.

### FIELD OF THE INVENTION

The present invention relates to a process for manufacturing a non-volatile memory electronic device integrated on a semiconductor substrate.

More particularly, but not exclusively, the present invention relates to a process for manufacturing a non-volatile memory electronic device comprising memory cells having a floating gate electrode with a reduced reading disturbance, and the following description is made with reference to this field of application by way of illustration only.

### BACKGROUND OF THE INVENTION

Non-volatile memory electronic devices, for example of the Flash type, integrated on a semiconductor substrate comprises a plurality of non-volatile memory cells organized in a matrix, i.e., the cells are organized in rows called word lines, and columns called bit lines.

Each single non-volatile memory cell comprises a MOS transistor wherein the gate electrode, arranged above the channel region, is floating. That is, the gate electrode has a high continuous impedance towards all the other terminals of the same cell and of the circuit wherein the cell is inserted.

The cell also comprises a second electrode, called a control gate, which is capacitively coupled to the floating gate electrode by an intermediate dielectric layer, called interpoly. This second electrode is driven by a suitable control voltage. The other electrodes of the transistor are the usual drain and source terminals.

The cells belonging to a same word line share the electric line which drives the respective control gates, while the cells belonging to a same bit line share the drain terminals.

Conventionally, memory electronic devices also comprise control circuitry associated with the matrix of memory cells. The control circuitry comprises conventional MOS transistors each having a source region and a drain region separated by a channel region. A gate electrode is then formed on the channel region and it is insulated therefrom by a gate oxide layer.

It is also known that the continuous scaling of the floating gate memory cells causes an increase of the reading disturbances of these memory cells linked to capacitive couplings between adjacent floating gate electrodes.

According to the most common schemes of the process used to form the cell matrix, and that is, with NAND and NOR architectures, a fundamental part of these reading disturbances is due to the coupling between floating gate electrodes of adjacent wordlines. This coupling between floating gate electrodes depends on the dimension of the floating gate electrode and, to a first approximation, it is proportional to the product of the width W of the memory cells and of the thickness of the polysilicon which forms the floating gate electrode. This coupling between floating gate electrodes also depends on the distance between the floating gate electrodes and on the dielectric constant of the materials which insulate the floating gate electrodes themselves from each other.

In particular, for the cells formed with architectures of the NAND type the coupling involves all the adjacent wordlines, since in this configuration the wordlines are uniformly spaced in the memory matrix. This is while in the cells formed with architectures of the NOR type with SAS architecture (Self-Aligned Source), the coupling involves only the wordlines which share a sourceline. Since the wordlines of the cells share a drain contact they are generally more spaced from each other to allow the housing of the drain contact to serve also as an electrostatic separator.

Moreover, the scaling of the reading disturbance due to the coupling between floating gate electrodes of adjacent wordlines is particularly remarkable in case of multilevel devices. It is also known, from U.S. Pat. No. 6,703,314, to manufacture self-aligned contacts in a semiconductor device, wherein voids are formed between conductive structures.

### SUMMARY OF THE INVENTION

An object of the present invention is to defining a process sequence for manufacturing a memory electronic device comprising a plurality of non-volatile memory cells of the floating gate type having such characteristics as to allow a decrease in the reading disturbances.

The process for manufacturing is based upon introducing air-gaps between the floating gate electrodes of the memory cells. More particularly, the process is for manufacturing a non-volatile electronic device integrated on a semiconductor substrate comprising a plurality of non-volatile memory cells organized in a matrix of rows and columns, with wordlines coupled to the rows and bit lines coupled to the columns, and comprising associated circuitry associated therewith.

The method may comprise forming gate electrodes for the non-volatile memory cells projecting from the semiconductor substrate, with each gate electrode comprising a first dielectric layer, a floating gate electrode on the first dielectric layer, a second dielectric layer on the floating gate electrode and a control gate electrode on the second dielectric layer. The control gate electrode may be coupled to a respective word line, and at least a first portion of the gate electrodes may be separated from each other by a first opening having a first width.

Source and drain regions are formed for the memory cells in the semiconductor substrate, with the source and drain regions being aligned with the gate electrodes of the memory cells. Gate electrodes are formed for transistors of the associated circuitry projecting from the semiconductor substrate, with each gate electrode for the associated circuitry comprising a first dielectric layer and a first conductive layer.

Source and drain regions are formed for the transistors in the semiconductor substrate. The source and drain regions are aligned with the gate electrodes for the transistors. On the whole device, a third non-conforming dielectric layer is deposited so as to not completely fill in the first openings and to form air-gaps between the gate electrodes belonging to the first portion of the gate electrodes of the memory cells.

Another aspect of the present invention is directed to a non-volatile memory electronic device integrated on a semiconductor substrate as defined above.

### BRIEF DESCRIPTION OF THE DRAWINGS

The characteristics and the advantages of the device according to the invention will be apparent from the following description of an embodiment thereof given by way of indicative and non-limiting example with reference to the annexed drawings. In these drawings:

FIGS. 1A to 9A are respective schematic section views of an integrated circuit portion during the successive steps of a first embodiment of a manufacturing process according to the present invention;

FIGS. 1B to 9B are respective schematic section views of an integrated circuit portion during the successive steps of a second embodiment of a manufacturing process according to the present invention;

FIGS. 10A and 11A are respective schematic section views of an integrated circuit portion during the successive steps of a first version of the first embodiment of a manufacturing process according to the present invention;

FIGS. 10B and 11B are respective schematic section views of an integrated circuit portion during the successive steps of a first version of the second embodiment of a manufacturing process according to the present invention;

FIGS. 12 and 13 are respective schematic section views of an integrated circuit portion during the successive steps of a second version of the second embodiment of a manufacturing process according to the present invention.

FIG. 14 is a schematic view from above of an integrated circuit portion of FIGS. 6A and 6B.

### DETAILED DESCRIPTION OF THE PREFERRED EMBODIMENTS

With reference to the figures, a process for manufacturing a non-volatile memory electronic device will now be described. The process steps and the structures described hereafter do not form a complete process flow for the manufacture of integrated circuits. Only the process steps commonly used and necessary for comprehension of the present invention will be discussed.

The figures showing cross sections of integrated circuit portions during manufacturing are not drawn to scale, but they are instead drawn so as to show the important characteristics of the invention. The process steps are then described for manufacturing a non-volatile memory electronic device integrated on a semiconductor substrate which comprises a plurality of non-volatile memory cells organized in a matrix, i.e., the cells are organized in rows called word lines, and columns called bit lines.

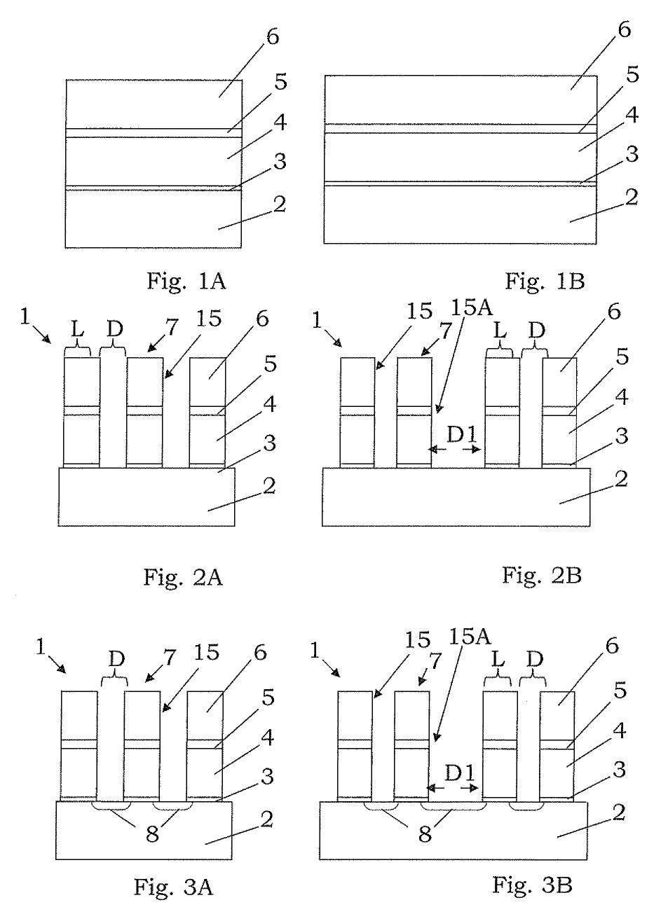

In particular, with reference to FIGS. 1A to 9A and 14, the process steps are shown for manufacturing a memory electronic device comprising a plurality of memory cells 1 organized with a NAND architecture and integrated on a semiconductor substrate 2.

The steps comprise forming active areas for the memory cells 1 delimited by a suitable insulation layer not shown in the figures, and forming in sequence on the whole semiconductor substrate 2, at least one first dielectric layer 3. For example, an active oxide also known as tunnel oxide is formed, and a first conductive layer 4, for example polysilicon, is formed.

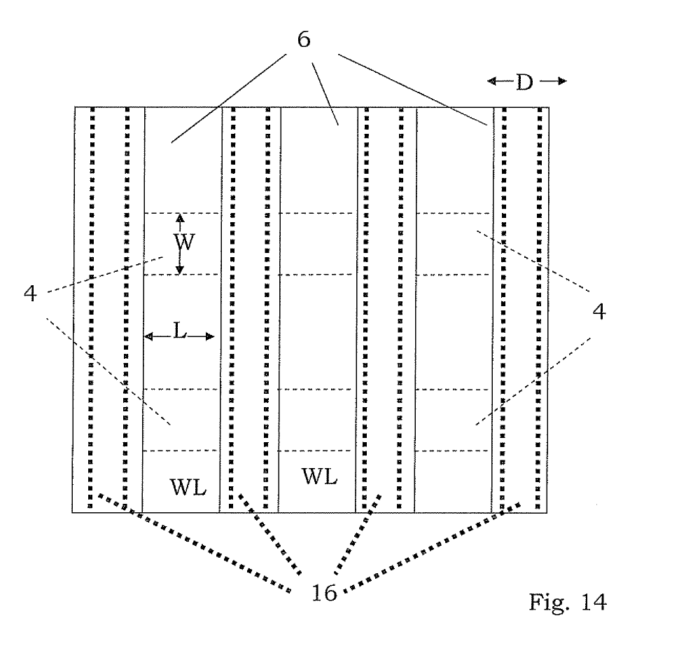

The method further comprises forming a first protective mask on the first conductive layer 4, etching the first conductive layer 4 through the first mask to define floating gate electrodes of the memory cells 1 having width W along a first direction, as shown in FIG. 14. These floating gate electrodes also having reference number 4.

The method further comprises forming, in sequence on the whole semiconductor substrate 2, at least one second dielectric layer 5, for example interpoly oxide and a second conductive layer 6, for example polysilicon. A second protective mask is formed on the second conductive layer 6 to define gate electrodes of the memory cells 1 in a second direction perpendicular to the first direction.

In sequence, the second conductive layer 6, the second dielectric layer 5, the first conductive layer 4 and the first dielectric layer 3 are etched through the second mask until the semiconductor substrate 2 is exposed so as to form openings 15 of width D and to complete the gate electrodes 7 of the memory cells 1 having a length L as shown in FIG. 2A.

In particular, with this latter etching step in the second conductive layer 6, the word lines WL of the matrix of memory cells 1 are defined. The portions of word lines WL aligned with the floating gate electrodes 4 form control gate electrodes of the memory cells which are also indicated with reference number 6.

For an architecture of the NAND type the gate electrodes 7 and thus the wordlines connecting them are uniformly spaced, usually with the distance which is equal to the width D of the openings 15 and is equal to the minimum allowed by the lithographic process used since contacts between the memory cells 1 are not provided. For example, for a process of 90 nm, i.e., wherein the minimum photolithographic resolution which can be obtained is equal to 90 nm, the distance D is for example equal to 90 nm while the length L is equal to 90 nm.

Moreover, in a known way, in the circuitry of the matrix at least one first dielectric layer of the circuitry, for example oxide, and one first conductive layer of the circuitry, for example polysilicon, are formed to manufacture gate electrodes of transistors of the circuitry, by a conventional photolithographic technique and successive etching of the first conductive layer of the circuitry and of the first dielectric layer of the circuitry.

Advantageously, the first conductive layer of the circuitry is formed by the second conductive layer 6 used to form the memory cells 1.

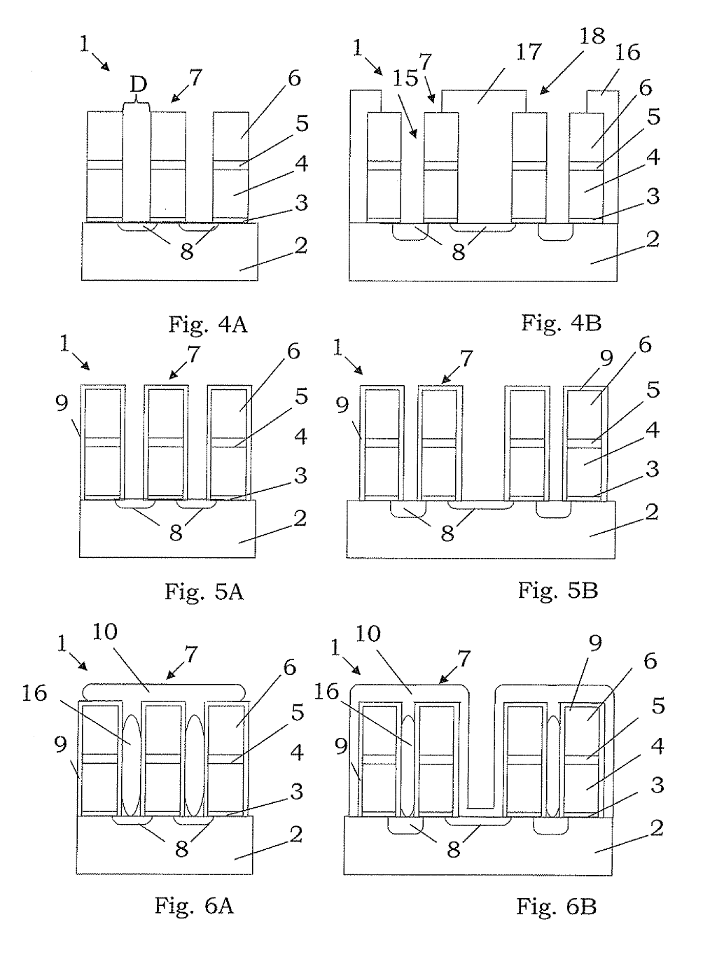

As shown in FIGS. 3A and 4A, the implants are carried out being self-aligned to the gate electrodes 7 to form the source and drain regions 8 of the memory cells 1, optimized according to the operation needs of the memory cells 1. In particular, these source and drain regions 8 are optimized to allow the sole reading of the memory cells arranged with NAND configuration. An implant step is then carried out to form first portions of source and drain regions of the circuitry transistors.

Advantageously, the memory cells 1 and the circuitry transistors are sealed by a step of re-oxidation of the source and drain regions 8 and the formation of a third thin dielectric layer, if any, for example of oxide, as shown in FIG. 5A. The group of the oxide layer formed by the re-oxidation step and of the dielectric layer deposited will be indicated with reference number 9.

Thus, once the gate electrodes 7 of the memory cells 1 have been completely formed, as described, in a fully conventional way, according to the invention, on the whole device, a fourth nonconforming dielectric layer 10 is deposited, as shown in FIG. 6A.

Due to the poor filling capacities of the fourth dielectric layer 10 and of a marked over-hang on the high part of the memory cells 1, the openings 15 are only plugged or closed on top and they are not completely filled in, with the consequent creation of air-gaps 16 which insulate the gate electrodes 7 of the memory cells 1 themselves from each other. The presence of the air-gaps 16 between the gate electrodes 7 drastically reduces the average dielectric constant between the gate electrodes 7 of the adjacent memory cells 1. This allows a significant scaling of the reading disturbance relative to the cells belonging to adjacent wordlines. In fact, these air-gaps 16 have a unitary dielectric constant which is equal to a fourth of one of the silicon oxide layers and to a seventh of one of the silicon nitride layers which are materials commonly used as filling layers of the memory matrix.

Advantageously, the fourth dielectric layer 10 is a layer of material having significant over-hang or a layer with a low step coverage capacity, i.e., with low capacity of filling slots. For example, the fourth dielectric layer 10 is formed by a nitride layer or by an oxide layer or by an oxynitride layer of the non conform type.

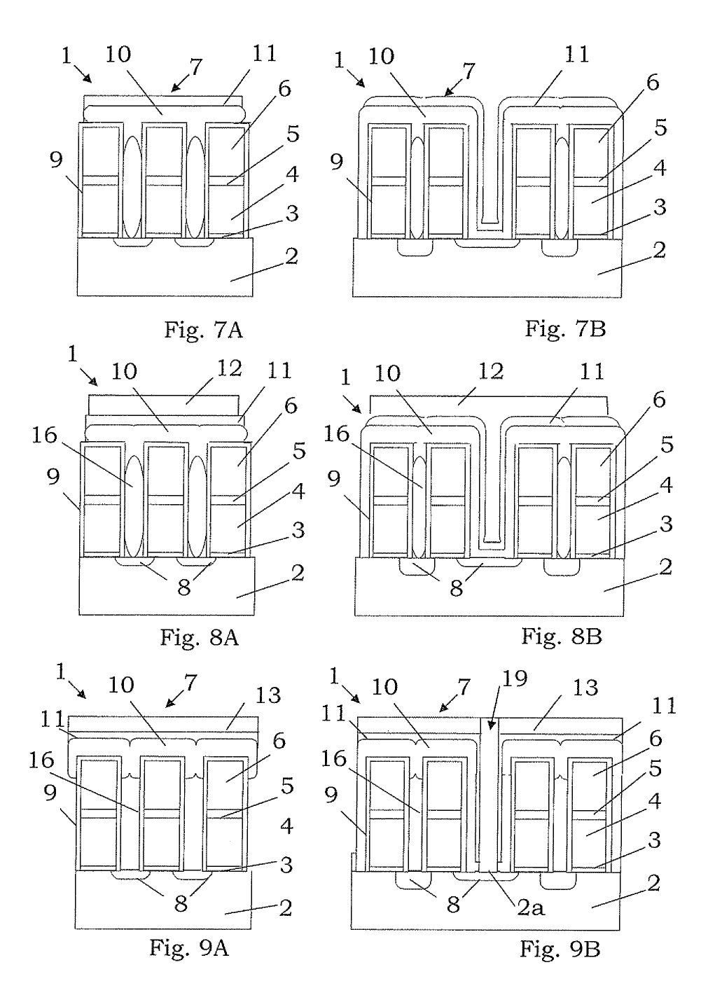

Advantageously, on the fourth dielectric layer 10 a fifth dielectric layer 11 with a high step coverage is deposited, i.e., with a high covering capacity, as shown in FIG. 7A. Advantageously, this fifth dielectric layer 11 is formed by an oxide or nitride layer or silicon oxynitride.

Advantageously from the combination of the fourth dielectric layer 10 and of the fifth dielectric layer 11, which can be formed separately or by a single integrated deposition, also the height at which the air-gaps 16 are formed inside the openings 15 can be controlled.

Advantageously, the fourth dielectric layer 10 and the fifth dielectric layer 11, if present, are used to form the spacers of the circuitry transistors. In fact, the circuitry transistors are more spaced from each other with respect to the memory cells 1 and thus they are much less affected by the filling problems linked to the fourth dielectric layer 10. Therefore, this layer completely covers the gate electrodes of the circuitry transistors and the semiconductor substrate 2 not covered by these gate electrodes.

At this point the steps for completing the spacers of the circuitry transistors can be formed by two different versions aimed at preserving the air-gaps 16 formed in the memory cells 1. In particular, as shown in FIG. 8A, on the memory cells 1 a mask 12 is formed, for example of resist, which protects the memory cells 1 during an etching step of the fourth dielectric layer 10 and of the fifth dielectric layer 11 to form spacers on the side walls of the circuitry transistors. This etching step is carried out until the dielectric layer 9 is exposed. Subsequently, a mask 12 is removed.

Once the definition of the circuitry transistors is conventionally completed, for example with further implant steps to form second source and drain portions aligned with the spacers and more doped with respect to the first portions of the source and drain regions, after having carried out a removal step of the dielectric layer 9, if any, a salicide layer 14 is formed on the surface portions of the gate electrodes of the circuitry transistors and on the circuitry exposed portions of the semiconductor substrate 2.

This salicide layer 14 is not formed in the matrix since it is covered by the fourth dielectric layer 10. Subsequently, at least one sixth premetal dielectric layer 13 is deposited on the whole device. Further openings are then defined in the sixth premetal dielectric layer 13 to form contacts in the circuitry.

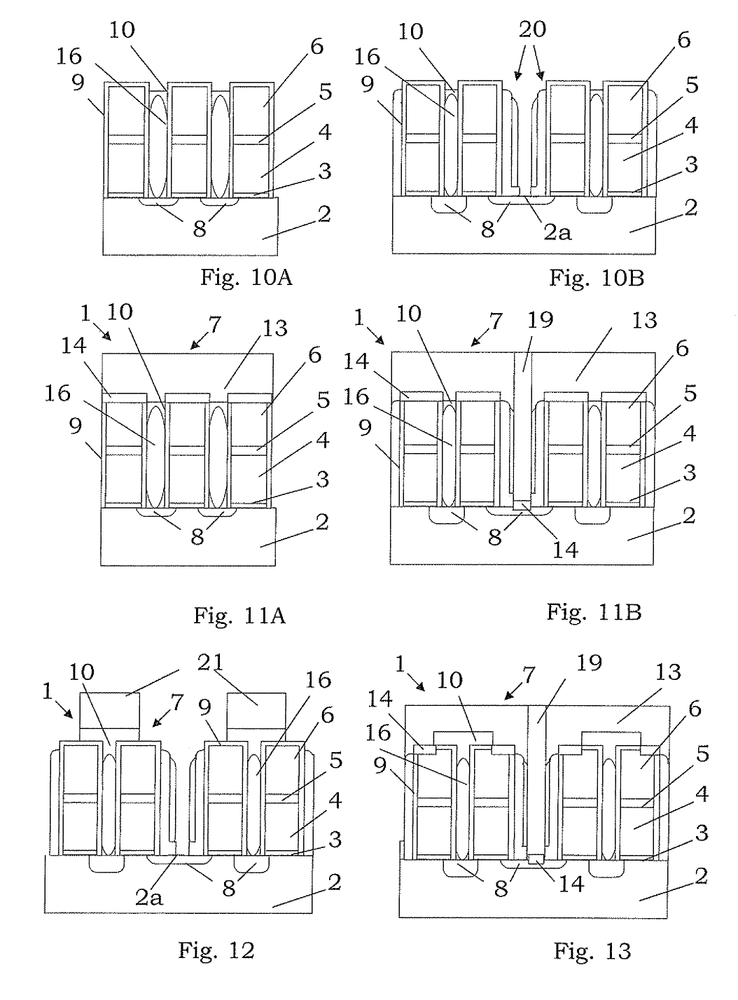

A second embodiment to complete the spacers of the circuitry transistors is shown with reference to FIGS. 10A and 11A. In particular, the etching step of the fourth dielectric layer 10 and of the fifth dielectric layer 11, if present, for the formation of the spacers of the circuitry transistors, is carried out on the whole device without the use of masks.

In particular, the etching step of the fourth dielectric layer 10 completely removes this fourth dielectric layer 10 from a surface portion of the gate electrodes 7, as shown in FIG. 10A, from surface portions of the gate electrodes of the circuitry transistors, from portions of the semiconductor substrate in circuitry not covered by the gate electrodes and spacers of the circuitry transistors. This etching step is carried out until the dielectric layer 9 is exposed.

Therefore, in the portions of the memory electronic device wherein the air-gaps 16 are created, the thickness of the fourth dielectric layer 10, and of the fifth dielectric layer 11, if any, need to be sufficient to ensure that the etching step of the circuitry spacers leaves the air-gaps 16 protected.

Once the definition of the circuitry transistors has been conventionally completed, for example, with further implant steps to form second portions of the source and drain regions aligned with the spacers and more doped with respect to the first portions of the source and drain regions, after having carried out a removal step of the dielectric layer 9 a salicide layer 14 is formed in the circuitry, if any, and on the gate 7 electrodes of the memory cells.

This salicide layer 14 is not formed on the source and drain regions of the matrix since covered by the fourth dielectric layer 10. Subsequently, at least one sixth premetal dielectric layer 13 is formed on the whole device as shown in FIG. 11A. Further openings are then defined in the sixth premetal dielectric layer 13 to form contacts in the circuitry.

With reference to FIGS. 1B to 11B, 12, 13 and 14, the steps are shown to manufacture a memory electronic device comprising a plurality of memory cells 1 organized instead with a NOR architecture integrated on a semiconductor substrate 2 which houses a contact inside the memory matrix.

In the following description, structural and functional elements being identical with respect to the process to manufacture memory cells 1 organized instead with a NOR architecture described with reference to FIGS. 1A-11A will be given the same reference numbers.

In particular, the manufacturing process comprises the steps of forming active areas for the memory cells 1 delimited by a suitable insulation layer not shown in the figures, forming in sequence on the whole semiconductor substrate 2 at least one first dielectric layer 3, for example of active oxide also known as tunnel oxide, and one first conductive layer 4, for example polysilicon.

The method further comprises forming a first protective mask on the first conductive layer 4, and etching the first conductive layer 4 through the first mask to define floating gate electrodes of the memory cells 1 of width W along a first direction, as shown in FIG. 14. These floating gate electrodes are also indicated with reference number 4.

The method further comprises forming, in sequence on the whole semiconductor substrate 2, at least one second dielectric layer 5, for example interpoly oxide and one second conductive layer 6, for example polysilicon. A second protective mask is formed on the second conductive layer 6 to define the gate electrodes of length L of the memory cells 1 in a second direction, for example perpendicular to the first direction. The second conductive layer 6, the second dielectric layer 5, the first conductive layer 4 and the first dielectric layer 3 are etched in sequence through the second mask until portions of the semiconductor substrate 2 are exposed so as to form first openings 15 of width D and second openings 15A of width D1.

In particular, with this latter etching step, in the second conductive layer 6 the word lines WL of the matrix of memory cells 1 are defined. The portions of word lines WL aligned with the floating gate electrodes 4 form control gate electrodes of the memory cells also indicated with reference number 6.

After having formed the word lines, a first portion of gate electrodes 7 of the memory cells 1 is then formed, and thus word lines, which are spaced from each other by a distance which is equal to the width D of the openings 15, and a second portion of gate electrodes 7 of the memory cells 1, and thus word lines, are spaced from each other by a distance which is equal to the width D1 of the openings 15A. These electrodes 7 of the memory cells 1 have a length L as shown in FIG. 2B.

In particular, the width D1 is greater than the width D, since it needs to be wide enough to house a contact of the matrix of cells of the memory electronic device.

For an architecture of the NOR type the width D of the openings 15 is determined by the minimum source line resistance which can be tolerate and it must be equal or higher than the minimum allowed by the lithographic process used. For example, for a process of 90 nm the distance D is equal to 120 nm. The distance D1 provides the presence of the drain contact and it is for example equal to 300 nm. The length L depends on the characteristics of the channel region and on the junctions of the cell, and is typically equal to double of the minimum allowed by the lithographic process used, for example 180 nm for a process of 90 nm.

Moreover, in a known way, in the circuitry associated with the memory matrix at least one first circuitry dielectric layer of the circuitry, for example oxide, and one first conductive layer of the circuitry, for example polysilicon, are formed to manufacture gate electrodes of the circuitry transistors. This is done by using a conventional photolihographic technique and successive etching of the first conductive layer of the circuitry and of the first dielectric layer of the circuitry.

Advantageously, the first conductive layer of the circuitry and the first dielectric layer of the circuitry are formed by the second conductive layer 6, and the second dielectric layer 5 used to form the memory cells 1.

As shown in FIGS. 33, the self-aligned implants are carried out through the openings 15 and 15A to form source and drain regions 8 of the memory cells 1 aligned with the gate electrodes 7, and are optimized according to the operation needs of the memory cells 1. In particular, to allow the reading and the programming for Channel Hot Electrons of the memory cells with a NOR architecture. Advantageously, by way of a successive implant step first portions of source and drain regions of the circuitry transistors are formed.

As shown in FIG. 4B, a photolithographic mask 17 is formed on the whole device being provided with third openings 18 aligned with first openings 15. Through these third openings 18, in a known way, a portion of the matrix insulation layer is removed to define a common source region of the memory matrix and a common source line is implanted in the semiconductor substrate 2, more doped with respect to the previously formed source and drain regions 8.

Advantageously, the memory cells 1 and the circuitry transistors are sealed by a re-oxidation step of the source and drain regions 8 and the formation of a third thin dielectric layer, if any, for example of oxide, as shown in FIG. 5B. The group of the oxide layer formed by the re-oxidation step and of the dielectric layer deposited will be indicated with reference number 9.

Once the gate electrodes 7 of the memory cells 1 have been completely formed, in a totally conventional way, according to the invention, a third dielectric layer 10 of the nonconforming type is deposited, as shown in FIG. 6B.

Due to the poor filling capacities of the fourth dielectric layer 10, the openings 15 are only plugged or closed on top and they are not completely filled in, with the consequent creation of the air-gaps 16 which insulate from each first portion of gate electrodes 7 of the memory cells 1 themselves. As already highlighted, the presence of the air-gaps 16 between the gate electrodes 7 of the memory cells 1 drastically reduces the mean dielectric constant between the gate electrodes 7 of the adjacent memory cells 1, allowing a significant scaling of the reading disturbance relative to cells belonging to adjacent wordlines.

The fourth dielectric layer 10 will instead completely coat the openings 15A since the width D1 of the openings 15A is wide enough to house contacts between the memory cells 1. In other words, the dielectric layer 10 follows the profile of the sides of the opening 15A, thus resulting to be, inside the openings 15A, of the conforming type.

For example, the fourth dielectric layer 10 is formed by a nitride layer or by an oxide layer or by an oxynitride layer with significant over-hang or with a low capacity of filling in the slots. Advantageously, after the formation of the fourth dielectric layer 10 a fifth dielectric layer 11 is deposited with a high capacity of filling in slots as shown in FIG. 7B.

From the combination of the fourth dielectric layer 10 and of the fifth dielectric layer 11, which can be formed separately or by a single integrated deposition, the height at which the air-gaps 16 are formed can also be controlled.

The fourth dielectric layer 10 and the fifth dielectric layer 11, if present, are advantageously used to form the spacers of the circuitry transistors. In fact, the circuitry transistors are more spaced from each other with respect to the memory cells 1 for which they are not affected by the problems of poor filling capacity of the fourth dielectric layer 10. Therefore, this layer 10 completely coats the gate electrodes of the circuitry transistors and the semiconductor substrate 2 whereon they are formed.

At this point of the process according to the invention, the steps for completing the spacers of the circuitry transistors can be formed by three different versions aimed at safeguarding the air-gaps 16 formed on the memory cells 1.

In particular, as shown in FIG. 8B, on the memory cells 1 a mask 12 is formed, for example of resist, which protects all the memory cells 1 during the etching step of the fourth dielectric layer 10 and of the fifth dielectric layer 11, if present, to form spacers on the side walls of the circuitry transistors. This also exposes portions of the semiconductor substrate 2 not covered by the gate electrodes and spacers of the circuitry. The mask 12 is then removed.

Once the definition for the circuitry transistors has been conventionally completed, for example with further implants to form second portions of the source and drain regions more doped with respect to the first portions of the source and drain regions and after a removal step of the layer 9, and after the formation of salicide layers in circuitry, if any. The formation of the salicide layer which is not formed in the matrix since it is covered by the fourth dielectric layer 10. At least one sixth premetal dielectric layer 13 is deposited, as shown in FIG. 9B.

Further openings 19 are then defined in the sixth premetal dielectric layer 13 to form contacts in the matrix and in the circuitry. A second version to complete the spacers of the circuitry transistors is shown with reference to FIGS. 10B and 11B.

In particular, the etching step of the fourth dielectric layer 10 and of the fifth dielectric layer 11, if present, for the formation of the spacers of the circuitry transistors is carried out on the whole device without using masks. Therefore, in the portions of the memory electronic device wherein the air-gaps 16 have been created, the thickness of the dielectric layer 10 and of the fifth dielectric layer 11, if present, need to be enough to ensure that the spacers etching step leave the air-gaps 16 protected.

Moreover, during the etching step of the fourth dielectric layer 10, inside the second openings 15A, spacers 20 are created on the side walls of the memory cells 1. In particular, the formation step of the spacers 20 of the matrix and of the circuitry spacers leave a surface portion of the gate electrodes 7 exposed and a portion 2a of the semiconductor substrate 2 aligned with the spacers 20 and not covered by the gate electrodes and by the spacers, both covered by the dielectric layer 9.

Once the definition of the circuitry transistors has been conventionally completed, for example with further implant steps to form second portions of the source and drain regions aligned with the spacers and more doped with respect to the first portions of the source and drain regions, after a removal step of the dielectric layer 9 from the surface portion of the gate electrodes 7 and from the portion 2a of the semiconductor substrate 2, a salicide layer 14 is formed in circuitry, if any, and on the gate electrodes 7 of the memory cells and on the portions 2a of the semiconductor substrate 2 which are exposed in matrix.

At least one sixth premetal dielectric layer 13 is then deposited on the whole device. Further openings 19 are then formed in the sixth premetal dielectric layer 13 to form contacts in the matrix and in the circuitry.

A second embodiment to complete the spacers of the circuitry transistors is described with reference to FIGS. 12 and 13. In particular, the definition of the circuitry spacers is carried out also in matrix with a mask 21 which protects the source regions, i.e., which covers the device portion wherein the air-gaps 16 are formed.

Therefore, after having formed the mask 21, the fourth dielectric layer 10 and the fifth dielectric layer 11 are etched, if present, until portions of the semiconductor substrate 2 not covered by the gate electrodes and by the spacers are exposed, which is then coated by the dielectric layer 9. Inside the second openings 15A coated by the fourth layer 10, spacers 20 are then formed on the side walls of the memory cells 1 besides spacers on the side walls of the circuitry transistors.

In particular, the formation step of the spacers 20 of the matrix and of the circuitry spacers leaves a surface portion of the gate electrodes 7 exposed and a portion 2a of the semiconductor substrate 2 not covered by the gate electrodes 7 and by the spacers 20 of the memory cells, coated by the dielectric layer 9.

Once the definition of the circuitry transistors has been conventionally completed, for example with further implant steps to form second portions of the source and drain regions more doped with respect to the first portions of the source and drain regions, once the dielectric layer 9 is removed from the surface portion of the gate electrodes 7 and from the portion 2a of the semiconductor substrate 2, a salicide layer 14 is formed in circuitry, if any, and on the gate electrodes 7 of the memory cells and on the portions 2a of the semiconductor substrate 2 which are exposed in matrix.

At least one sixth premetal dielectric layer 13 is then deposited on the whole device. Further openings 19 are then defined in the sixth premetal dielectric layer 13 to form contacts in the matrix and in the circuitry.

Although the process according to the invention has been described with reference to memory cells of the Flash type, it can be advantageously applied to memories of the EPROM type, a Flash EEPROM with NAND or NOR organizations, being one-level or multilevel. The memory cells are provided with a floating gate electrode.

In conclusion, with the process according to the invention, the electrostatic disturbance between cells of adjacent wordlines is scaled down due to the smaller mean dielectric constant of the materials which separate the wordlines.

Moreover, the air-gaps 16 having been defined are advantageously self-aligned with the wordlines and their formation provides the use of common materials which do not have particular compatibility constraints with the rest of the process. Therefore, the compatibility with the processes being currently in use is complete and the additional process steps do not involve particular constraints for the definition of the circuitry.

Moreover, with the continuous scaling of the non-volatile memory electronic devices, the process according to the invention can be advantageously used to improve the characteristics of the devices with matrixes having high density memory matrixes, in particular those with multilevel operation.

The advantages of the process according to the invention are particularly significant for memory devices with a NAND configuration, which mainly suffer from reading disturbances linked to the coupling of the floating gate electrodes of adjacent wordlines. For these memories the introduction of the air-gaps 16 according to the invention requires, at the most, the addition of a non-critical mask to the conventional process flow.

Advantageously, at the morphologic level, memory electronic devices formed with the process according to the invention can be easily recognized in the matrix due to the presence of the air-gaps 16 and the morphology of the layer 10 that is formed by non conforming material and is used as protection of the air-gaps 16, being it nitride, oxide or oxynitride.

1-15. (canceled)

16. A process for manufacturing an electronic device integrated on a semiconductor substrate comprising a plurality of non-volatile memory cells organized in a matrix of rows and columns, with wordlines coupled to the rows and bit lines coupled to the columns, and comprising circuitry associated therewith, the method comprising:
forming gate electrodes projecting from the semiconductor substrate for the non-volatile memory cells, each gate electrode comprising a first dielectric layer, a floating gate electrode on the first dielectric layer, a second dielectric layer on the floating gate electrode and a control gate electrode on the second dielectric layer, the control gate electrode being coupled to a respective wordline, and at least a first portion of the gate electrodes being separated from each other by a first opening having a first width;
forming source and drain regions in the semiconductor substrate for the memory cells, with the source and drain regions being aligned with the gate electrodes of the memory cells;
forming gate electrodes projecting from the semiconductor substrate for transistors of the circuitry associated with the plurality of non-volatile memory cells, each gate electrode comprising a first dielectric layer and a first conductive layer thereon;
forming source and drain regions in the semiconductor substrate for the transistors of the circuitry, with the source and drain regions being aligned with the gate electrodes of the transistors; and
depositing a third dielectric layer on the gate electrodes and on the source and drain regions while not completely filling in the first openings so that air-gaps are formed between the gate electrodes of the at least first portion of the gate electrodes.

17. A process according to claim 16, wherein the third dielectric layer comprises at least one of a nitride layer, an oxide layer and an oxynitride layer.

18. A process according to claim 16, wherein the third dielectric layer completely covers the transistors in the circuitry associated with the plurality of non-volatile memory cells.

19. A process according to claim 16, further comprising forming a fourth dielectric layer on the third dielectric layer, the fourth dielectric layer having a high step coverage.

20. A process according to claim 19, wherein the fourth dielectric layer comprises at least one of an oxide layer, a nitride layer and an oxynitride layer.

21. A process according to claim 18, further comprising:
forming a dielectric layer on the transistors in the circuitry associated with the plurality of non-volatile memory cells before forming the third dielectric layer; and
etching the third dielectric layer to form spacers on side walls of the transistors until at least one portion of the semiconductor substrate is exposed.

22. A process according to claim 16, wherein a second portion of the gate electrodes of the memory cells is separated from each other by a second opening having a second width greater than the first width, and wherein the third dielectric layer covers the second openings.

23. A process according to claim 21, wherein during the etching of the third dielectric layer spacers are formed on the side walls of the gate electrodes of the second portion of the gate electrodes of the memory cells which are inside the second openings, the etching exposing at least one portion of the semiconductor substrate, covered by a dielectric layer formed on the electronic device before forming the third dielectric layer.

24. A process according to claim 23, wherein during the etching step of the third dielectric layer surface portions of the gate electrode are exposed.

25. A process according to claim 21, wherein before carrying out the etching step of the third dielectric layer, further comprising forming a mask on at least the first portion of the gate electrodes of the memory cells.

26. A process according to claim 25, wherein before carrying out the etching step of the third dielectric layer, further comprising forming a mask on all the gate electrodes of the memory cells.

27. A process according to claim 23, wherein a siliciuro layer is formed on the at least one exposed portion of the semiconductor substrate after having removed the dielectric layer.

28. A process according to claim 24, wherein a siliciuro layer is formed on the exposed surface portions of the gate electrodes after having removed the dielectric layer.

29. A process according to claim 23, wherein a contact is formed on the at least one exposed portion of the semiconductor substrate.

30. A process for manufacturing an electronic device comprising:
forming a plurality of non-volatile memory cells organized in a matrix of rows and columns on a semiconductor substrate;
forming wordlines coupled to the rows and forming bit lines coupled to the columns of the non-volatile memory cells;
forming the plurality of memory cells comprising
forming gate electrodes projecting from the semiconductor substrate, each gate electrode comprising a first dielectric layer, a floating gate electrode on the first dielectric layer, a second dielectric layer on the floating gate electrode and a control gate electrode on the second dielectric layer, the control gate electrode being coupled to a respective wordline, and at least a first portion of the gate electrodes being separated from each other by a first opening having a first width, and
forming source and drain regions in the semiconductor substrate for the memory cells, with the source and drain regions being aligned with the gate electrodes of the memory cells;
forming circuitry on the semiconductor substrate comprising transistors associated with the plurality of non-volatile memory cells, the forming comprising
forming gate electrodes projecting from the semiconductor substrate for the transistors, each gate electrode comprising a first dielectric layer and a first conductive layer thereon, and
forming source and drain regions in the semiconductor substrate for the transistors, with the source and drain regions being aligned with the gate electrodes of the transistors; and
depositing a third dielectric layer on the gate electrodes and on the source and drain regions while not completely filling in the first openings so that air-gaps are formed between the gate electrodes of the at least first portion of the gate electrodes.

31. A process according to claim 30, wherein the third dielectric layer comprises at least one of a nitride layer, an oxide layer and an oxynitride layer.

32. A process according to claim 30, further comprising forming a fourth dielectric layer on the third dielectric layer, the fourth dielectric layer having a high step coverage.

33. A process according to claim 32, wherein the fourth dielectric layer comprises at least one of an oxide layer, a nitride layer and an oxynitride layer.

34. A process according to claim 31, further comprising:
forming a dielectric layer on the transistors in the circuitry associated with the plurality of non-volatile memory cells before forming the third dielectric layer; and
etching the third dielectric layer to form spacers on side walls of the transistors until at least one portion of the semiconductor substrate is exposed.

35. A process according to claim 30, wherein a second portion of the gate electrodes of the memory cells is separated from each other by a second opening having a second width greater than the first width, and wherein the third dielectric layer covers the second openings.

36. A process according to claim 34, wherein during the etching of the third dielectric layer spacers are formed on the side walls of the gate electrodes of the second portion of the gate electrodes of the memory cells which are inside the second openings, the etching exposing at least one portion of the semiconductor substrate, covered by a dielectric layer formed on the electronic device before forming the third dielectric layer.

37. A process according to claim 36, wherein during the etching step of the third dielectric layer surface portions of the gate electrode are exposed.

38. A process according to claim 36, wherein a siliciuro layer is formed on the at least one exposed portion of the semiconductor substrate after having removed the dielectric layer.

39. A process according to claim 37, wherein a siliciuro layer is formed on the exposed surface portions of the gate electrodes after having removed the dielectric layer.

40. An electronic device comprising:
a semiconductor substrate;
a plurality of non-volatile memory cells organized as a matrix of rows and columns on said semiconductor substrate;
wordlines coupled to the rows, and bit lines coupled to the columns of said matrix of memory cells;
circuitry on said semiconductor substrate and associated with said plurality of non-volatile memory cells;
each memory cell comprising:
a gate electrode projecting from said semiconductor substrate and comprising a first dielectric layer, a second dielectric layer on said floating gate electrode, and a control gate electrode on said second dielectric layer, said control gate electrode being coupled to a respective wordline, and
source and drain regions on said semiconductor substrate and aligned with said gate electrode; and
a third dielectric layer on at least one portion of said gate electrodes being insulated from each other by first air-gaps which are closed on top by said third dielectric layer.

41. An electronic device according to claim 40, wherein said third dielectric layer comprises at least one of a nitride layer, an oxide layer and an oxynitride layer.

42. An electronic device according to claim 40, further comprising a fourth dielectric layer on the third dielectric layer, the fourth dielectric layer having a high step coverage.

43. An electronic device according to claim 42, wherein the fourth dielectric layer comprises at least one of an oxide layer, a nitride layer and an oxynitride layer.

44. An electronic device according to claim 40, further comprising a dielectric layer between said third dielectric layer and said gate electrodes of said transistors in the circuitry associated with the plurality of non-volatile memory cells; and wherein said third dielectric layer forms spacers on a portion of the side walls of the transistors except where the first air-gaps are formed.

45. An electronic device according to claim 40, wherein the first air-gaps have a first width; and wherein a second portion of said gate electrodes of said memory cells is separated from each other by second air-gaps having a second width greater than the first width, and wherein the second air-gaps are closed on top by said third dielectric layer.

46. An electronic device according to claim 40, wherein a siliciuro layer is on a portion of said semiconductor substrate.

47. An electronic device according to claim 40, wherein a contact is formed on a portion of said semiconductor substrate.
